(19) United States
(12) Patent Application Publication
(10) Pub. No.: US 2025/0176203 A1
(43) Pub. Date: May 29, 2025

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: Chuan-Cheng Tsou, Hsinchu (TW); Yi-Ping Chao, Hsinchu (TW); Jung-Chi Jeng, Hsinchu (TW); Chen-Chieh CHIANG, Hsinchu (TW)

(73) Assignee: Taiwan Semiconductor Manufacturing Company, Ltd., Hsinchu (TW)

(21) Appl. No.: 18/519,271

(22) Filed: Nov. 27, 2023

(51) Int. Cl. H01L 29/66; H01L 21/8234; H01L 27/088; H01L 29/08; H01L 29/78

(52) U.S. Cl. CPC H10D 30/024; H10D 30/62; H10D 62/151; H10D 84/013; H10D 84/014; H10D 84/0158; H10D 84/038; H10D 84/834

(57) ABSTRACT

A semiconductor device and a manufacturing method thereof are provided. The semiconductor device comprises a substrate, a plurality of fin structures and a gate structure. The fin structures are disposed on the substrate. The gate structure is formed on the fin structures and is substantially perpendicular to the fin structures. Each of the fin structures includes a first source/drain region and a second source/drain region, and the gate structure is located between the first source/drain region and the second source/drain region, and at least one of the fin structures is electrically floated between the first source/drain region and the second source/drain region.

### BACKGROUND

The electronics industry has a growing demand for smaller and faster electronic devices that can simultaneously support a greater number of increasingly complex functions. Accordingly, there is a continuing trend in the semiconductor industry to manufacture low cost, high performance and low power integrated circuits (ICs). So far, these goals have been achieved largely by reducing IC dimensions (e.g., minimum feature size) of a semiconductor to increase production efficiency and reduce associated manufacture costs. However, this technique of reducing the IC dimensions of the semiconductor also increases the complexity of the semiconductor manufacturing process. Therefore, in order to cope with the continuous improvement and IC technologies of semiconductor, the semiconductor manufacturing processes and related technologies also need to be improved.

Recently, multi-gate devices have been introduced into fin field-effect transistors (FinFETs). FinFETs have been used in various applications, for example, to implement logic devices/circuits and to provide static random-access memory (SRAM) devices or the like. Generally speaking, logic devices may focus on electrical performance (e.g., threshold voltage, saturation current, and breakdown voltage etc.), while SRAM devices may focus on optimizing the size of memory cells and improving operating voltages of memory cells and other requirements. However, optimization of the performance and/or design requirements of FinFET devices has been challenging.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic diagram of a semiconductor device according to an embodiment of the disclosure.

FIG. 2 is an example of a multi-gate semiconductor device along the B-B′ section of FIG. 1.

FIG. 3A is a schematic top view of a semiconductor device according to an embodiment of the disclosure.

FIG. 3B is a schematic top view of a semiconductor device according to another embodiment of the disclosure.

FIG. 3C is a schematic top view of a semiconductor device according to another embodiment of the disclosure.

FIGS. 4A to 4D are schematic top views of semiconductor devices according to different embodiments of the disclosure.

FIGS. 5A to 5E are schematic top views of semiconductor devices according to different embodiments of the disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The semiconductor device of the present disclosure presents embodiments in the form of a multi-gate transistor or a fin multi-gate transistor, referred to herein as a fin field-effect transistor (FinFET) device. Such FinFET devices include P-type metal-oxide-semiconductor FinFET devices or N-type metal-oxide-semiconductor FinFET devices. FinFET devices can be dual-gate devices, tri-gate devices, bulk devices, silicon-on-insulator devices, or other configurations. For example, some embodiments as described herein can also be applied to a gate-all-around device (GAA device), an Omega-gate device (Ω-gate), or a π-type gate device (Pi-gate device).

FinFET devices have become popular candidates for high performance and low leakage applications (e.g., for logic devices and/or circuits). In various examples, FinFET devices employ narrow fin widths for short channel control, improved Ion/Ioff ratio, and continuously variable gate lengths. Additionally, FinFET devices with multiple fins have been used in high-speed applications, but such devices still suffer from increased current leakage and power consumption. In some embodiments, a single fin FinFET device may be used to mitigate current leakage and power consumption issues, but this may also result in a reduction in the speed of the FinFET device. Embodiments of the present disclosure can alleviate the current leakage and power consumption issues of the FinFET device with multiple fins, and also avoid the reduction in the speed of the FinFET device.

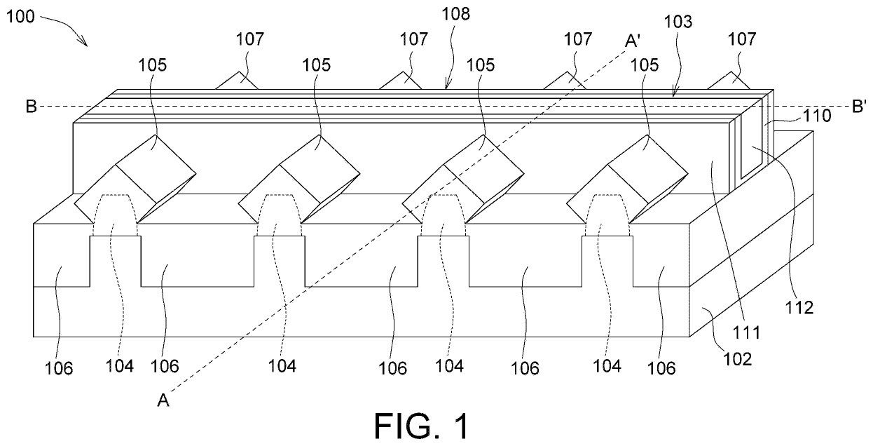

Referring to FIG. 1, a three-dimensional schematic diagram of a semiconductor device 100 is provided. The semiconductor device 100 is a fin-based multi-gate field effect transistor. The semiconductor device 100 includes a substrate 102, multiple fin structures 104 extending from the substrate 102, an isolation region 106, and a gate structure 108 disposed on and around the fin structures 104. The substrate 102 may be a semiconductor substrate, such as a silicon substrate. The substrate 102 may include an insulating layer formed on the semiconductor substrate. The substrate 102 may include various doping configurations according to design requirements known in the art. The substrate 102 may also include other semiconductors, such as germanium, silicon carbide (SiC), silicon germanium (SiGe) or diamond. Alternatively, the substrate 102 may include compound semiconductors and/or alloy semiconductors. Furthermore, in some embodiments, the substrate 102 may include an epitaxial layer (epi-layer) or SOI (silicon-on-insulator) structure.

The fin structures 104 may include silicon or other elemental semiconductors, such as germanium. Compound semiconductors include silicon carbide, gallium arsenide, gallium phosphide, indium phosphide, indium arsenide and/or indium antimonide). Alloy semiconductors include SiGe, GaAsP, AlInAs, AlGaAs, InGaAs, GaInP, and/or GaInAsP, or combinations thereof. The fin structures 104 may be fabricated using suitable processes including photolithography and etch processes. The photolithography process may include forming a photoresist layer covering the substrate 102, exposing the photoresist layer to form a pattern by performing a post-exposure bake process, and a masking element is used to form the pattern included in the photoresist layer. In some embodiments, patterning the photoresist layer to form the fabricated device may be performed using an e-beam lithography process. The photoresist layer may be used to protect areas of the substrate 102, and then recesses are formed in the silicon layer during an etch process for leaving the extended fin structures 104. The method of etching the recesses includes dry etching, wet etching and/or other suitable methods. The fin structures 104 on the substrate 102 may also be formed using other embodiments.

Each of the plurality of fin structures 104 includes a first source/drain region 105 and a second source/drain region 107, the first source/drain region 105 and the second source/drain region 107 are formed in, over and/or around the fin structures 104. The source/drain regions 105 and 107 may be epitaxially grown on the fin structures 104. The channel region 103 of the transistor is disposed within the fin structures 104 and below the gate structure 108 along a plane substantially parallel to the plane defined by section A-A′ of FIG. 1. In some examples, the channel regions 103 of the fin structures 104 include a high mobility material, such as germanium, any of the compound semiconductors or alloy semiconductors discussed above, and/or combinations thereof. High mobility materials include those materials that have greater electron mobility than silicon. For example, in some embodiments, the high mobility material may be a silicon-based material having an intrinsic electron mobility of about 1350 cm²/V-s and a hole mobility of about 480 cm²/V-s above room temperature (300 K).

The isolation region 106 may be a shallow trench isolation (STI) feature, or a field oxide, a local oxidation of silicon (LOCOS) feature and/or other suitable isolation features on and/or within the substrate 102. The isolation region 106 can be composed of the following materials: silicon oxide, silicon nitride, silicon oxynitride, fluorine-doped silicate glass (FSG), low-k dielectrics, combinations thereof, and/or other suitable materials known in the art. In one embodiment, the STI feature can be formed into an isolation structure in the substrate 102 by etching trench technology. The trenches may then be filled with isolation material and subjected to a chemical mechanical polishing (CMP) process. In some embodiments, isolation region 106 may include a multi-layer structure, e.g., having one or more liner layers.

The gate structure 108 includes a gate stack, the gate stack includes a gate dielectric layer 110 and a gate electrode layer 112 formed above the gate dielectric layer 110. In some embodiments, the gate dielectric layer 110 may include an interfacial layer formed on the channel region 103 of the fins 104 and a high-K dielectric layer above the interfacial layer. The interface layer of the gate dielectric layer 110 may include a dielectric material, such as a silicon oxide layer (SiO₂) or a silicon oxynitride (SiON). The high-K dielectric layer of the gate dielectric layer 110 may include: HfO₂, TiO₂, HfZrO, Ta₂O₃, HfSiO₄, ZrO₂, ZrSiO₂, combinations thereof, or other suitable materials. In other embodiments, the gate dielectric layer 110 may include silicon dioxide or other suitable dielectrics. The gate dielectric layer 110 can be deposited by chemical oxidation, thermal oxidation, atomic layer deposition (ALD), physical vapor deposition (PVD), chemical vapor deposition (CVD) and/or other suitable methods.

The gate electrode layer 112 may include a conductive layer, for example, W, TIN, TaN, WN, Re, Ir, Ru, Mo, Al, Cu, Co, Ni, combinations thereof and/or other suitable compositions. In some embodiments, the gate electrode layer 112 may include a first group of metal materials for N-type FinFET and a second group of metal materials for P-type FinFET. Accordingly, the semiconductor device 100 may include a dual work-function metal gate configuration. For example, the first metallic material (for an N-type device) may comprise a metal having a work function substantially aligned with that of the substrate conduction band, or at least substantially aligned with a work function of the conduction band of the channel region of the fin structures 104. Likewise, for example, the second metallic material (for a P-type device) may comprise a metal having a work function substantially aligned with that of the conduction band of the substrate, or at least substantially aligned with a work function of the conduction band of the channel regions 103 of the fin structures 104. Accordingly, the gate electrode layer 112 may provide a gate electrode to the semiconductor device 100, including N-type and P-type FinFET devices. In some embodiments, the gate electrode layer 112 may include polysilicon layers alternately stacked. The gate electrode layer 112 may be formed using physical vapor deposition (PVD), chemical vapor deposition (CVD), electron beam evaporation, and/or other suitable processes. In some embodiments, sidewall spacers 111 are formed on sidewalls of the gate structure 108. The sidewall spacers 111 may include dielectric materials such as silicon oxide, silicon nitride, silicon carbide, silicon oxynitride or combinations thereof.

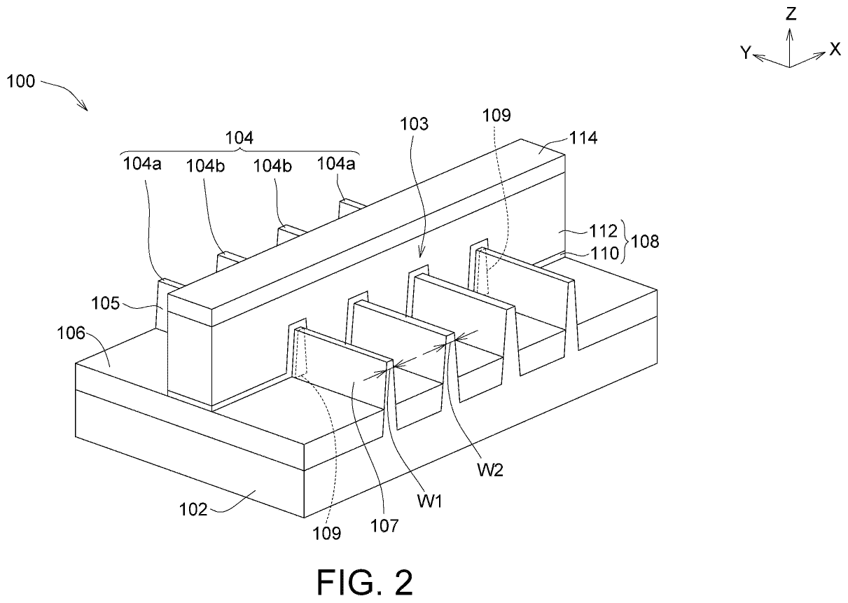

FIG. 2 is an example of a multi-gate semiconductor device 100 along the B-B′ section of FIG. 1. The gate structure 108 includes a gate dielectric layer 110, a gate electrode layer 112 and a hard mask layer 114. The hard mask layer 114 may include any material suitable for respectively patterning the gate electrode layer 112 with specific dimensions and/or attributes, including silicon nitride, silicon oxynitride, silicon carbonitride or a combination thereof, etc. The hard mask layer 114 may be deposited by CVD, PVD, ALD, or other deposition techniques. In some embodiments, the gate structure 108 further includes a capping layer and/or other suitable layers. The gate structure 108 engages the fins 104 on two or three sides of the fins 104 so as to be inserted between the source/drain regions 105, 107 of each fin such that the current can flow between the source/drain regions 105, 107 during operation.

For example, in the FinFET device of FIG. 2, the gate structure 108 surrounds three sides of each fin structures 104 (and channel regions 103), allowing increased control of channel regions 103. The gate structure 108 includes a gate electrode layer 112 and a gate oxide layer 110. The gate electrode layer 112 overlaps the gate oxide layer 110. The gate structure 108 is formed between the source region 105 and the drain region 107 and is located above the channel region 111.

In one embodiment, the fin structures 104 include a first type of fin (also referred to as edge fins 104a) and a second type of fin (also referred to as center fins 104b) disposed on the substrate 102. The number of fins is greater than or equal to 3. The fin structures 104 extend substantially parallel to each other along a second direction (e.g., Y direction) and a third direction (e.g., Z direction), and each fin structures 104 has a length defined in the second direction (e.g., Y direction), a width defined in the first direction (e.g., X direction), and a height defined in the third direction (e.g., Z direction). This disclosure considers changes in the height, width, and/or length of the fin structures 104 that may result from etching process and manufacturing precision. For example, in FIG. 2, the width of the fin structures 104 changes from the upper portion of each fin to the lower portion of each fin. In the depicted embodiment, the width tapers from the lower portion of the fin to the upper portion of the fin such that the average width of the upper portion is less than the average width of the lower portion. In some embodiments, the width along the fin structures 104 may vary from about 3 nm to about 20 nm, depending on where the width of the fin structures 104 is measured. In some embodiments, the width of the fin structures 104 varies depending on the position of the fins relative to each other and/or the position of the fin structures 104 relative to other portions of the semiconductor device 100. For example, the width W2 of the center fin 104b may be greater than the width W1 of the edge fin 104a. In another embodiment, the center fin 104b may alternatively have a smaller width than the edge fin 104a. In both embodiments, the width W1 of edge fin 104a may represent the average width of edge fin 104a, and the width W2 of center fin 104b may represent the average width of center fin 104b.

For example, the difference between the average width of the center fin 104b and the average width of the edge fin 104a may be from about 3 nm to about 10 nm. As shown in FIG. 2, each fin has at least one channel region 103, at least one source region 105 and at least one drain region 107 defined along its length in the second direction (e.g., Y direction), the channel regions 103 is disposed between the source region 105 and the drain region 107 (commonly referred to as source/drain regions 105, 107). The channel region 103 includes a top defined between two sidewall portions, where the top and sidewall portions engage the gate electrode layer 112 such that the current can flow between the source/drain regions 105, 107 during operation.

In one embodiment, in order to avoid the problem of poor reliability (such as time-dependent dielectric breakdown (TDDB) and breakdown voltage (V_{bd}) burn-out) of the edge fin 104a with a smaller width, the electrical function of the edge fin 104a can be cut off and/or the edge fin 104a is electrically floated to the source/drain contacts to prevent the two outermost edge fins 104a of the fin structure 104 from working properly, thereby ensuring that the reliability of the fin structures 104 is increased.

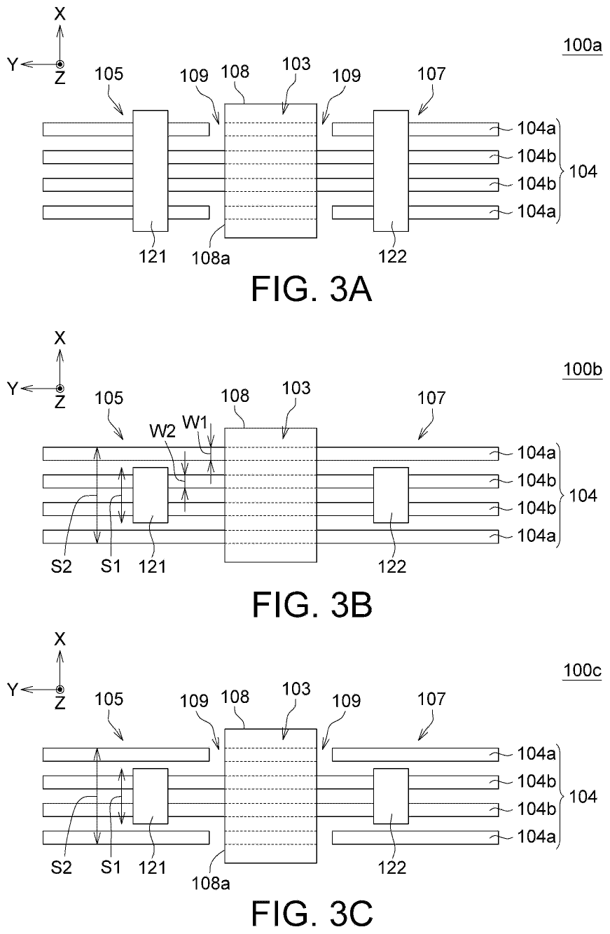

Referring to FIG. 3A, a top view of a semiconductor device 100a according to an embodiment of the present disclosure is provided. The semiconductor device 100a includes a substrate (illustration omitted), a plurality of fin structures 104 and a gate structure 108. The fin structures 104 are disposed on the substrate. The number of the fin structures 104 may be three or more, including two edge fins 104a and at least one center fin 104b. The gate structure 108 is formed on the fin structures 104 and is substantially perpendicular to the fin structures 104. The fin structures 104 include a first source/drain region 105 and a second source/drain region 107. The gate structure 108 is located between the first source/drain region 105 and the second source region 107, and in at least one fin (such as the edge fins 104a) of the fin structures 104, the first source/drain region 105 and the second source/drain region 107 are electrically floated from each other. As shown in FIG. 3A, the two outermost edge fins 104a of the fin structure 104 are formed with a groove 109, for example, using a suitable process including photolithography and etching processes. The groove 109 is adjacent to the sidewall portion 108a of gate structure 108. In one embodiment, for example, a mask layer (not shown) is formed on the fin structures 104. The mask layer is, for example, a photoresist layer or plasma enhanced oxide (PEOX). A portion of the photoresist layer is removed through processes such as exposure and development to expose a portion of the edge fins 104a to be removed. Next, the edge fin 104a is subjected to anisotropic etching, plasma etching, wet chemical etching and/or other types of etching to form a groove 109. In one embodiment, the remained edge fins 104a in the channel regions 103 are not removed. That is to say, the etched groove 109 is formed in the etching process after the gate structure 108 is formed. Therefore, the groove 109 is located outside the gate structure 108 and not within the region where the gate structure 108 is located.

In one embodiment, the groove 109 is located between the first source/drain region 105 of the edge fins 104a and the gate structure 108 and/or is located between the second source/drain region 107 of the edge fins 104a and gate structure 108.

Referring to FIG. 3A, the semiconductor device 100a includes a first source/drain contact 121 and a second source/drain contact 122. The first source/drain contact 121 is disposed on the first source/drain region 105, the second source/drain contact 122 is disposed on the second source/drain region 107. The first source/drain contact 121 spans the edge fins 104a and is electrically coupled to the edge fins 104a. The second source/drain contact 122 spans the edge fins 104a and is electrically coupled to the edge fins 104a. However, since the two edge fins 104a are electrically floated between the first source/drain region 105 and the second source/drain region 107, the two edge fins 104a are disabled to operate normally.

Referring to FIG. 3B, a top view of a semiconductor device 100b according to an embodiment of the present disclosure is provided. In this embodiment, the semiconductor device 100b includes a first source/drain contact 121 and a second source/drain contact 122. The first source/drain contact 121 is disposed on the first source/drain contact 121, the second source/drain contact 122 is disposed on the second source/drain region 107. The number of the fin structures 104 may be three or more, including two edge fins 104a and at least one center fin 104b. The difference between this embodiment and the above-mentioned embodiments is that in at least one fin (such as the edge fins 104a) of the fin structures 104, the first source/drain contact 121 and the second source/drain contact 122 are electrically floated from each other. As shown in FIG. 3B, the first source/drain contact 121 has a first size S1 in the first direction X, and the fin structures 104 have a second size S2 in the first direction X. The first The direction X is perpendicular to the extending direction of the fin structures 104. The first size S1 is smaller than the second size S2. In one embodiment, the first source/drain contact 121 spans the center fins 104b and is electrically coupled to the center fins 104b, but does not span the two outermost edge fines 104a of the fin structures 104, that is, the first dimension S1 is less than the second dimension S2 minus the width W1 of the two outermost edge fins 104a, S1<S2-2W1. In addition, the second source/drain contact 122 spans the center fin 104b and is electrically coupled to the center fins 104b, but does not span the two outermost edge fins 104a of the fin structures 104, that is, the first dimension S1 is less than the second dimension S2 minus the width W1 of the two outermost edge fins 104a, S1<S2-2W1.

In one embodiment, since the first source/drain contact 121 is not in contact with the two edge fins 104a, and the second source/drain contact 122 is not in contact with the two edge fins 104a, the edge fins 104a are electrically floated between the first source/drain contact 121 and the second source/drain contact 122, so that the two edge fins 104a are disabled to work properly.

Referring to FIG. 3C, a top view of a semiconductor device 100c according to an embodiment of the present disclosure is provided. In this embodiment, combined with the embodiment of FIG. 3A and the embodiment of FIG. 3B, it can be seen that the groove 109 is located between the first source/drain region 105 of the edge fins 104a and the gate structure 108 and/or is located between the second source/drain region 107 of the edge fin 104a and the gate structure 108, and the first source/drain contact 121 is not electrically coupled to the two edge fins 104a, and the second source/drain contact 122 is not electrically coupled to the two edge fins 104a, so that the two edge fins 104a are electrically floated between the first source/drain region 105 and the second source/drain region 107, therefore, the two edge fins 104a are disabled to work properly.

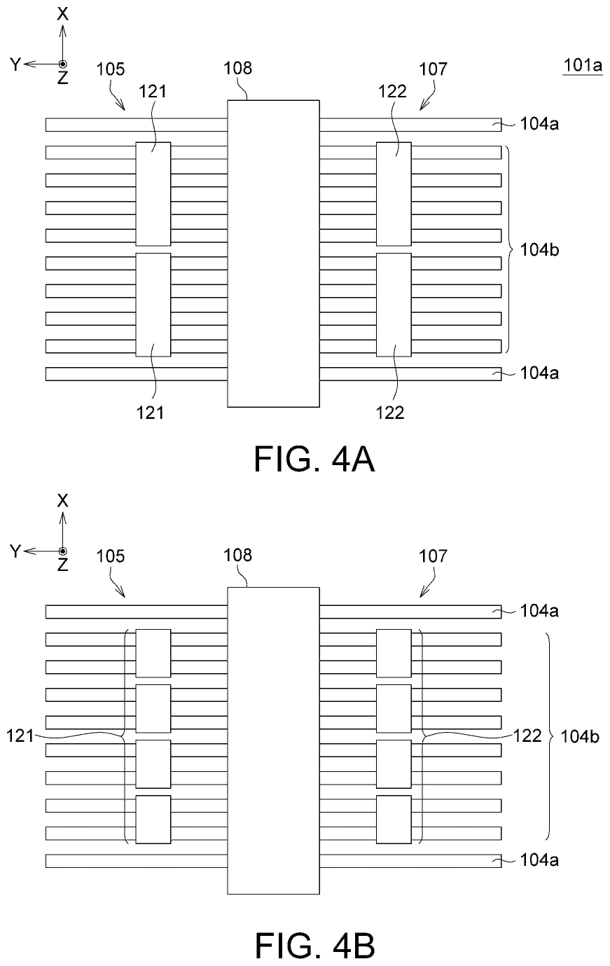

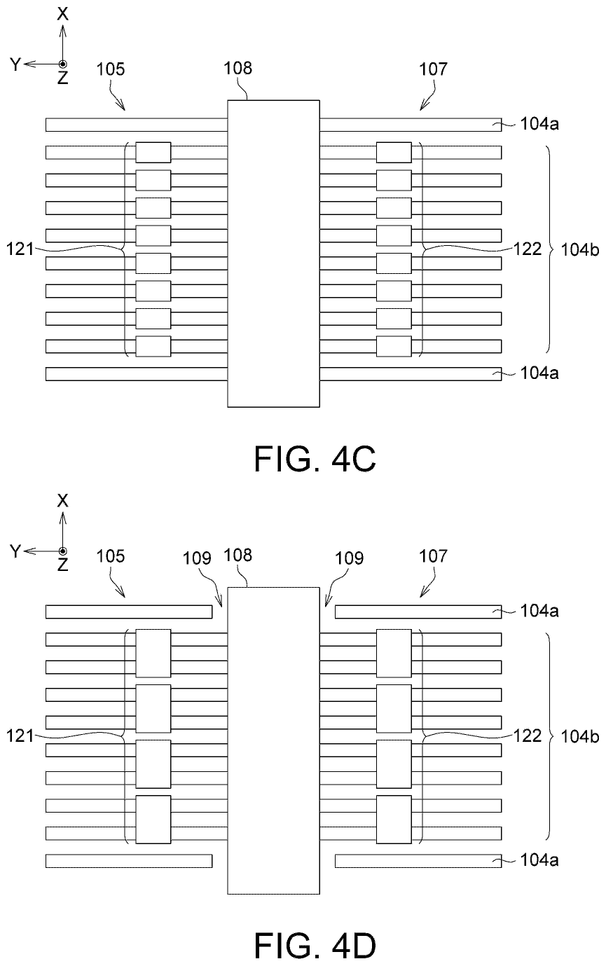

Referring to FIGS. 4A to 4D, top views of a semiconductor device 101a according to another embodiment of the present disclosure are provided. In FIGS. 4A to 4C, the number of the first source/drain contacts 121 may be two, four or eight, and the number of the second source/drain contacts 122 may be two, four or eight, but it is not limited thereto. Each of the first source/drain contacts 121 spans a predetermined number of center fins 104b, each of second source/drain contacts 122 spans a predetermined number of center fins 104b, and the first source/drain contact 122 spans a predetermined number of center fins 104b. The number of center fins 104b spanned by the source/drain contact 121 and the second source/drain contact 122 is the same, such as 1 to 4, but is not limited thereto.

In addition, each of the first source/drain contacts 121 can be connected to the same or different source/drain signals via an interconnection structure, and each of the second source/drain contacts 122 can be connected to the same or different source/drain signals via an interconnection structure, and the current can be controlled to pass between each of the first source/drain contacts 121 and the corresponding second source/drain contact 122 through the voltage signal of the gate structure 108.

In FIG. 4D, the configuration of the first source/drain contacts 121 and the second source/drain contacts 122 is similar to the configuration of FIG. 4A to 4C, and will not be described again. The difference is that in FIG. 4D, the groove 109 is located between the first source/drain region 105 of the edge fins 104a and the gate structure 108 and/or is located between the second source/drain region 107 of the edge fins 104a and the gate structure 108, so that the two edge fins 104a are electrically floated between the first source/drain region 105 and the second source/drain region 107, so that the two edge fins 104a are disabled to working properly.

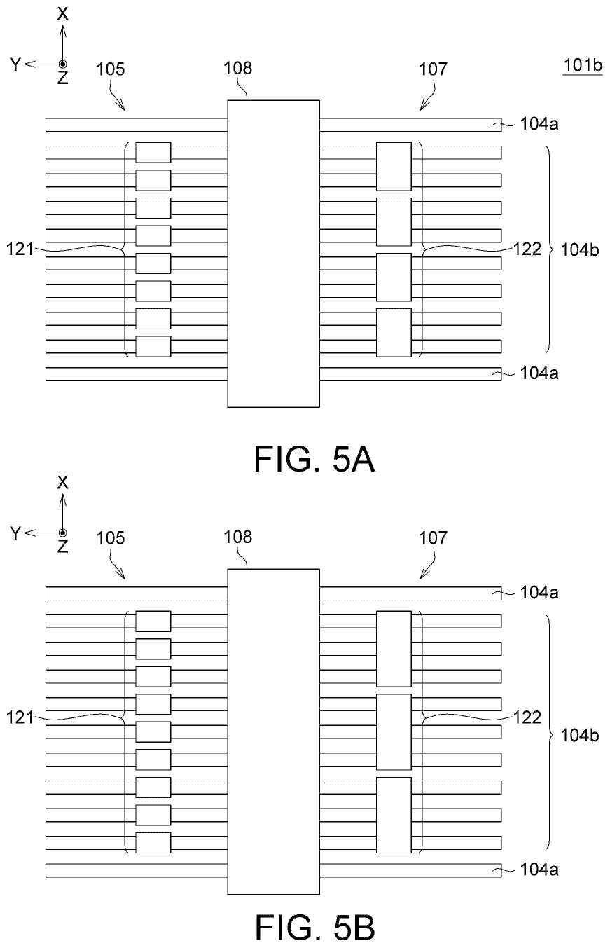

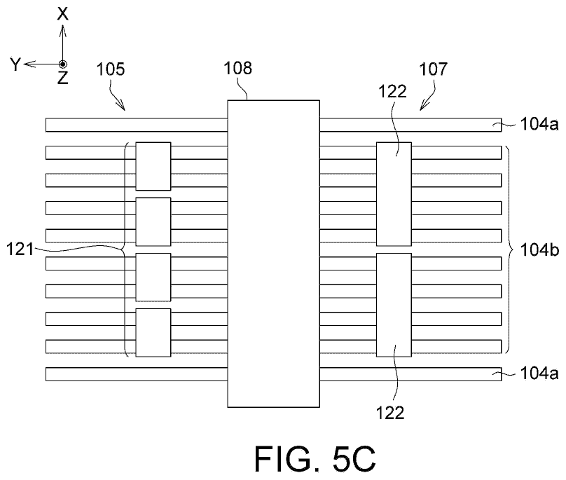

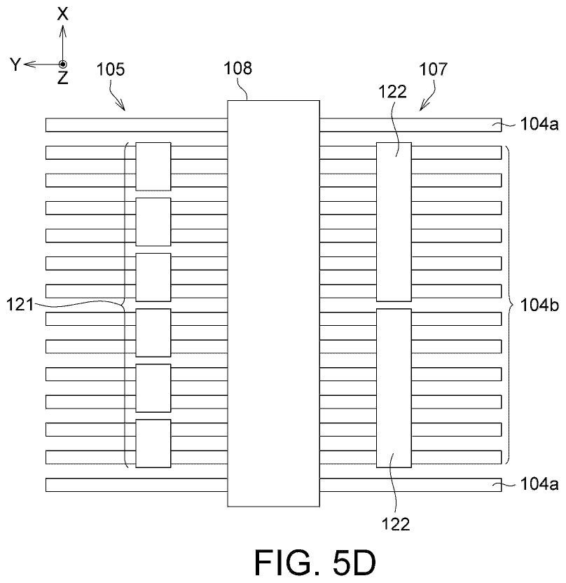

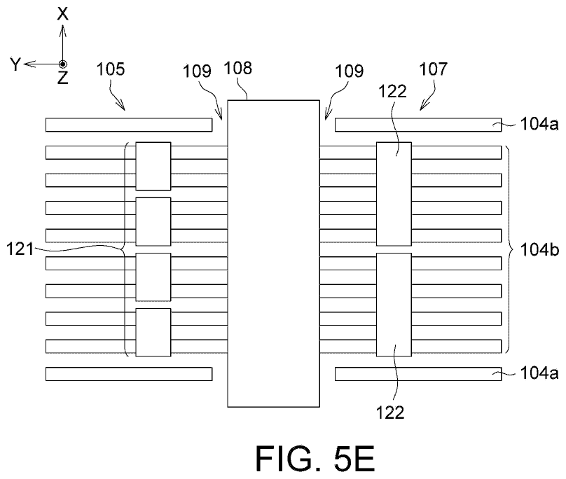

Referring to FIGS. 5A to 5E, schematic top views of semiconductor devices 101b according to different embodiments of the present disclosure are provided. In FIGS. 5A to 5D, the number of the first source/drain contacts 121 can be any number, such as four, six, eight or nine, and the number of the second source/drain contacts 122 can be any number, such as two, three, or four, but is not limited thereto. Each of the first source/drain contacts 121 spans a predetermined first number of center fins 104b, and each of the second source/drain contacts 122 spans a predetermined second number of center fins 104b, and the numbers of the first number of center fins 104b and the second number of center fins 104b are different. For example, the ratio of the first number to the second number is 1:2, 1:3 or 1:4, but it is not limited thereto.

In addition, in FIG. 5A, two first source/drain contacts 121 share a second source/drain contact 122. In FIG. 5B, three first source/drain contacts 121 share a second source/drain contact 122. In FIG. 5C, two first source/drain contacts 121 share a second source/drain contact 122. In FIG. 5D, three first source/drain contacts 121 share a second source/drain contact 122.

Therefore, in the above embodiments, the first source/drain contacts 121 and the second source/drain contacts 122 are configured in a 1-to-1, multiple-to-multiple, 1-to-multiple or multiple-to-1 configuration, for example. to meet actual needs.

In FIG. 5E, the configuration of the first source/drain contacts 121 and the second source/drain contacts 122 is similar to the configuration of FIGS. 5A to 5D, and will not be described again. The difference is that in FIG. 5E, the groove 109 is located between the first source/drain region 105 of the edge fins 104a and the gate structure 108 and/or is located between the second source/drain region 107 of the edge fins 104a and the gate structure 108, so that the two edge fins 104a are electrically floated between the first source/drain region 105 and the second source/drain region 107, and the two edge fins 104a is disabled to work properly.

The present disclosure relates to a semiconductor device and a manufacturing method thereof, in which the edge fin function was shut down by layout design to improve reliability of the fin structures so as to prevent time-dependent dielectric breakdown (TDDB) and breakdown voltage (V_{bd}) burn-out. In addition, shorten source/drain contacts that do not contact edge fins are used to disable the edge fin function to improve reliability quality of the fin structures.

According to some embodiments of the present disclosure, a semiconductor device includes a substrate, a plurality of fin structures and a gate structure. The fin structures are disposed on the substrate. The gate structure is formed on the fin structures and is substantially perpendicular to the fin structures. Each of the fin structures includes a first source/drain region and a second source/drain region, and the gate structure is located between the first source/drain region and the second source/drain region, and in at least one of the fin structures, the first source/drain region and the second source/drain region are electrically floated from each other.

According to some embodiments of the present disclosure, a semiconductor device includes a substrate, a plurality of fin structures, a gate structure, a first source/drain contact and a second source/drain contact. The fin structures are disposed on the substrate. The gate structure is formed on the fin structures and is substantially perpendicular to the fin structures. Each of the fin structures includes a first source/drain region and a second source/drain region, and the gate structure is located between the first source/drain region and the second source/drain region. The first source/drain contact is disposed on the first source/drain region, and the second source/drain contact is disposed on the second source/drain region. In at least one of the fin structures the first source/drain contact and the second source/drain contact are electrically floated from each other.

According to some embodiments of the present disclosure, a method of manufacturing a semiconductor device includes the following steps. A plurality of fin structures is formed on a substrate by etching process. Sidewalls of the fin structures are exposed from an isolation region of the substrate. A gate structure is formed on the fin structures and is substantially perpendicular to the sidewalls of the fin structures. Each of the fin structures includes a first source/drain region and a second source/drain region, the gate structure is located between the first source/drain region and the second source/drain region. In at least one of the fin structures, the first source/drain region and the second source/drain region are electrically floated from each other.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a plurality of fin structures disposed on the substrate; and
a gate structure formed on the fin structures and being substantially perpendicular to the fin structures, wherein each of the fin structures comprises a first source/drain region and a second source/drain region, the gate structure is located between the first source/drain region and the second source/drain region, and in at least one of the fin structures, the first source/drain region and the second source/drain region are electrically floated from each other.

2. The semiconductor device according to claim 1, wherein the fin structures comprise at least one edge fin and at least one center fin, the edge fin has at least one groove located on at least one position between the first source/drain region of the edge fin and the gate structure or between the second source/drain region of the edge fin and the gate structure, so that the edge fin is electrically floated.

3. The semiconductor device according to claim 2, wherein the groove is adjacent to a sidewall portion of the gate structure.

4. The semiconductor device according to claim 2, wherein the semiconductor device further comprises:
a first source/drain contact disposed on the first source/drain region, the first source/drain contact spans the edge fin and is electrically coupled to the edge fin; and
a second source/drain contact disposed on the second source/drain region, and the second source/drain contact spans the edge fin and is electrically coupled to the edge fin.

5. The semiconductor device according to claim 2, wherein the semiconductor device further comprises:
a first source/drain contact disposed on the first source/drain region, the first source/drain contact spans the center fin and is electrically coupled to the center fin; as well as
a second source/drain contact is disposed on the second source/drain region, the second source/drain contact spans the center fin and is electrically coupled to the center fin.

6. The semiconductor device according to claim 5, wherein the first source/drain contact and the second source/drain contact do not span the edge fin.

7. The semiconductor device according to claim 6, wherein the first source/drain contact has a first size in a first direction, and the fin structures have a first size in the first direction, the first size is smaller than the second size, and the first direction is perpendicular to an extension direction of the fin structures.

8. The semiconductor device according to claim 6, wherein the second source/drain contact has a first size in a first direction, and the fin structures have a first size in the first direction, the first size is smaller than the second size, and the first direction is perpendicular to an extension direction of the fin structures.

9. The semiconductor device according to claim 6, wherein a number of the first source/drain contact is multiple, a number of the second source/drain contact is multiple, the source/drain contacts and the second source/drain contacts are configured in a 1 to 1, multiple-to-multiple, 1-to-multiple or multiple-to-1.

10. The semiconductor device according to claim 9, wherein the first source/drain contacts respectively span a first number of the center fins, and the second source/drain contacts respectively span a second number of center fins, wherein the ratio of the first number to the second number is 1:1, 1:2, 1:3 or 1:4.

11. A semiconductor device, comprising:
a substrate;
a plurality of fin structures disposed on the substrate; and
a gate structure formed on the fin structures and being substantially perpendicular to the fin structures, wherein each of the fin structures comprises a first source/drain region and a second source/drain region, the gate structure is located between the first source/drain region and the second source/drain region;
a first source/drain contact disposed on the first source/drain region; and
a second source/drain contact disposed on the second source/drain region,
wherein in at least one of the fin structures, the first source/drain contact and the second source/drain contact are electrically floated from each other.

12. The semiconductor device according to claim 11, wherein the fin structures comprise at least one edge fin and at least one center fin, and the first source/drain contact spans the center fin and is electrically coupled to the center fin, and the second source/drain contact spans the center fin and is electrically coupled to the center fin.

13. The semiconductor device according to claim 12, wherein the first source/drain contact and the second source/drain contact do not span the edge fin.

14. The semiconductor device according to claim 13, wherein the first source/drain contact has a first size in a first direction, and the fin structures have a second size in the first direction, the first size is smaller than the second size, and the first direction is perpendicular to an extension direction of the fin structures.

15. The semiconductor device according to claim 13, wherein the second source/drain contact has a first size in a first direction, and the fin structures have a second size in the first direction, the first size is smaller than the second size, and the first direction is perpendicular to an extension direction of the fin structures.

16. The semiconductor device according to claim 13, wherein a number of the first source/drain contact is multiple, a number of the second source/drain contact is multiple, and the source/drain contacts and the second source/drain contacts are configured in a 1-to-1, multiple-to-multiple, 1-to-multiple or multiple-to-1.

17. The semiconductor device according to claim 16, wherein the first source/drain contacts respectively span a first number of the center fins, and the second source/drain contacts respectively span a second number of center fins, wherein a ratio of the first number to the second number is 1:1, 1:2, 1:3 or 1:4.

18. A method of manufacturing a semiconductor device, comprising:
forming a plurality of fin structures on a substrate by an etching process;
exposing sidewalls of the fin structures from an isolation region of the substrate; and
forming a gate structure on the fin structures, the gate structure is substantially perpendicular to the sidewalls of the fin structures, wherein each of the fin structures comprises a first source/drain region and a second source/drain region, the gate structure is located between the first source/drain region and the second source/drain region;
wherein in at least one of the fin structures, the first source/drain region and the second source/drain region are electrically floated from each other.

19. The method according to claim 18, wherein the fin structures comprise at least one edge fin and at least one center fin, and the manufacturing method of the semiconductor device further comprises forming at least one groove on the edge fin, the groove is located on at least one position between the first source/drain region of the edge fin and the gate structure or between the second source/drain region of the edge fin and the gate structure, so that the edge fin is electrically floated.

20. The method according to claim 18, further comprising:
forming a first source/drain contact on the first source/drain region; and
forming a second source/drain contact on the second source/drain region,
wherein the fin structures comprise at least one edge fin and at least one center fin, and the first source/drain contact and the second source/drain contact do not span the edge fin.
